(19) United States
(12) Patent Application Publication
(10) Pub. No.: US 2009/0183901 A1
(43) Pub. Date: Jul. 23, 2009

(54) Wiring Boards and Processes for Manufacturing the Same

(75) Inventors: Tatsuo Kataoka, Ageo-shi (JP); Hirokazu Kawamura, Ageo-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 11/836,522

(22) Filed: Aug. 9, 2007

(30) Foreign Application Priority Data
Aug. 11, 2006 (JP) 2006-220685

(51) Int. Cl. H05K 1/02; G03F 7/20

(52) U.S. Cl. 174/257; 430/314

(57) ABSTRACT

A wiring board includes an insulating substrate and a wiring pattern. The wiring pattern includes a main body and an upper end portion and is embedded in the insulating substrate while exposing at least the upper end portion on a surface of the insulating substrate. The upper end portion has a cross-sectional width smaller than that of a lower end portion of the wiring pattern embedded in the insulating substrate. The upper end portion is formed of a metal that is more noble than a metal of the main body of the wiring pattern.

The wiring board having this structure achieves very high adhesion of the wiring pattern to the insulating layer.

### FIELD OF THE INVENTION

The present invention relates to wiring boards in which a wiring pattern trapezoidal in cross section is embedded in an insulating substrate and thereby shows high adhesion to the insulating substrate. The invention also relates to processes for manufacturing a wiring board in which a wiring pattern trapezoidal in cross section is formed in an insulating substrate.

### BACKGROUND OF THE INVENTION

Wiring boards are used for mounting electronic components such as LSI in an electronic apparatus. The wiring board is manufactured by etching a three-layer film having a copper foil, an insulating film such as polyimide, and an adhesive film therebetween. With a need for finer wiring patterns, the three-layer films are replaced by two-layer CCL having a thinner metal layer. The subtractive etching of two-layer CCL can produce COF (chip-on-film) boards with an ultra fine pattern. In the ultra-fine-pattern COF board, the conductor has a narrow top width and a narrow bottom width. It is therefore necessary that the copper foil has a small thickness. However, reduced thickness of conductor can increase the conductor resistance and reduce the bonding reliability of an inner lead and an electronic component mounted thereon. Moreover, when a liquid crystal element is bonded to a COF board with an anisotropic conductive adhesive film (ACF), conduction failure is frequently caused.

The semi-additive process is another established technique for forming wiring patterns. This process can fabricate a thick conductor but entails selective removal of a seed layer for producing the conductor. The selective removal of the seed layer also reduces the conductor width. Consequently, when the conductor has fine pitches of not more than 20 μm, the conductor shows insufficient bond strength with the substrate and is often separated from the substrate.

Furthermore, even after the seed layer (Ni—Cr alloy) has been etched, the alloy can remain between the wires. When the wiring pattern has fine pitches of not more than 20 μm, migration of Ni or Cu is frequently caused.

In the wiring board manufacturing using three-layer films that have an electrodeposited copper foil, an insulating film and an adhesive film therebetween, the mat surface (M surface) of the electrodeposited copper foil is provided with nodules to increase the adhesion of the electrodeposited copper foil with the insulating film. However, because of the nodules, etching the electrodeposited copper foil tends to result in unsharp bottoms. Therefore, it is more difficult to produce a fine wiring pattern in this three-layer film than in the two-layer COF board. Moreover, the nodules should be provided even when the electrodeposited copper foil has a larger thickness. Furthermore, the use of a thin copper foil has limitations as described above.

There has been an increasing need for three-layer fine pitch TAB tapes in which inner leads are overhung, for increasing heat release from electronic components.

In the conventional wiring boards as described above, the wiring pattern having reduced pitches shows insufficient adhesion with the insulating layer, and the wires are nonuniform in line width to cause wide variation in characteristics such as electric resistance. Consequently, the conventional wiring boards are not suited for fine pitches because of such wide variation in characteristics.

JP-A-2006-49742 discloses a process for producing a tape carrier. This claimed process comprises depositing copper on a resin substrate on which a resist pattern has been formed as a reversed pattern of a wiring pattern; laminating a semi-cured resin film on the copper deposit pattern on the resin substrate; releasing the resin substrate together with the resist; and embedding the copper deposit pattern in the resin whereby the copper deposit forms a wiring having a flat surface and a flat and rectangular slope. This process is directed to producing wiring patterns that are rectangular in cross section, not trapezoidal as in the present invention.

### DISCLOSURE OF THE INVENTION

It is an object of the invention to provide wiring boards having a novel structure such that pitches in a wiring pattern are small while the wiring pattern shows high adhesion with an insulating substrate and is not separated from the insulating substrate.

It is another object of the invention to provide processes for manufacturing the novel wiring boards.

A wiring board according to the present invention comprises an insulating substrate and a wiring pattern, the wiring pattern including a main body and an upper end portion and being embedded in the insulating substrate while exposing at least the upper end portion on a surface of the insulating substrate, the upper end portion having a cross-sectional width smaller than that of a lower end portion of the wiring pattern embedded in the insulating substrate, the upper end portion comprising a metal which is more noble than a metal of the main body of the wiring pattern.

Preferably, the main body of the wiring pattern is embedded in the insulating substrate and an upper end surface of the upper end portion of the wiring pattern is exposed on the surface of the insulating substrate.

Preferably, the wiring board further comprises a nodule deposit layer on a lower end surface of the lower end portion of the wiring pattern, and at least the nodule deposit layer is embedded in the insulating substrate.

Preferably, the wiring pattern is embedded in the insulating substrate to a depth of at least 20% of the length of a slope of the wiring pattern from the lower end surface.

Preferably, the insulating substrate comprises at least one insulating resin selected from the group consisting of polyimides, epoxy resins, polyamic acids and polyamideimides. Preferably, the more noble metal forming the upper end portion of the wiring pattern exposed on the insulating substrate includes at least one metal selected from the group consisting of gold, silver and platinum. Preferably, the metal forming the main body of the wiring pattern is copper or a copper alloy. Preferably, the upper end portion of the wiring pattern has a cross-sectional width in the range of 40 to 99% of that of the lower end portion. Preferably, the upper end portion comprising the more noble metal has a thickness of 0.01 to 3 μm.

A first process for manufacturing the wiring board as described above comprises the steps of:

forming a photosensitive resin layer on a surface of a conductive support metal foil;

exposing the photosensitive resin layer and developing a latent image to form a groove for forming a wiring pattern, the groove having a bottom opening facing the conductive support metal foil, the bottom opening having a width smaller than that of a surface opening;

depositing a conductive metal on the conductive support metal foil exposed from the bottom opening of the groove, the conductive metal being more noble than a metal of the conductive support metal foil;

depositing a conductive metal on the noble conductive metal, the conductive metal being less noble than the noble conductive metal and filling the groove to form a wiring pattern;

removing the resin layer;

forming an insulating layer on the conductive support metal foil exposed by the removal of the resin layer, for embedding the wiring pattern in the insulating layer; and

removing the conductive support metal foil by etching to expose the insulating layer and the more noble metal forming an upper end portion of the wiring pattern.

A second process for manufacturing the wiring board as described above comprises the steps of:

forming a photosensitive resin layer on a surface of a conductive support metal foil;

exposing the photosensitive resin layer and developing a latent image to form a groove for forming a wiring pattern, the groove having a bottom opening facing the conductive support metal foil, the bottom opening having a width smaller than that of a surface opening;

depositing a conductive metal on the conductive support metal foil exposed from the bottom opening of the groove, the conductive metal being more noble than a metal of the conductive support metal foil;

depositing a conductive metal on the noble conductive metal, the conductive metal being less noble than the noble conductive metal and filling the groove to form a wiring pattern, and forming a nodule layer on a bottom of the wiring pattern;

removing the resin layer;

embedding the wiring pattern and the nodule layer in an insulating layer; and

removing the conductive support metal foil by etching to expose the insulating layer and the more noble metal forming an upper end portion of the wiring pattern.

A third process for manufacturing the wiring board as described above comprises the steps of:

half etching a conductive metal foil laminated on a flexible support resin film, the conductive metal foil and the flexible support resin film forming a composite support film in combination, the half etching resulting in a composite support having an extremely thin conductive metal layer;

applying a photosensitive resin on the extremely thin conductive metal layer of the composite support to form a photosensitive resin layer, and exposing the photosensitive resin layer and developing a latent image to form a groove for forming a wiring pattern, the groove having a bottom opening facing the extremely thin conductive metal layer, the bottom opening having a width smaller than that of a surface opening;

depositing a conductive metal on the extremely thin conductive metal layer exposed from the bottom opening of the groove, the conductive metal being more noble than a metal of the extremely thin conductive metal layer;

depositing a conductive metal on the noble conductive metal, the conductive metal being less noble than the noble conductive metal and filling the groove to form a wiring pattern, and forming a nodule layer on a bottom of the wiring pattern;

removing the resin layer;

embedding the wiring pattern and the nodule layer in an insulating layer; and

removing the conductive support metal foil by etching to expose the insulating layer and the more noble metal forming an upper end portion of the wiring pattern.

A fourth process for manufacturing the wiring board as described above comprises the steps of:

forming a photosensitive resin layer on a surface of a conductive support metal foil;

exposing the photosensitive resin layer and developing a latent image to form a groove in which the conductive support metal foil is exposed from the resin layer, the groove having a bottom opening facing the conductive support metal foil, the bottom opening having a width smaller than that of a surface opening;

half etching the conductive support metal foil with use of the resin layer as a masking material to form a recess in the conductive support metal foil;

forming a nodule layer on a surface of the recess of the conductive support metal foil, and depositing a metal layer in the recess in which the nodule layer has been formed, the metal layer comprising a metal that is more noble than a metal of the nodule layer;

depositing a metal in a recess which is defined by the resin layer and the half etched conductive support metal foil and includes the nodule layer and the more noble metal layer, the metal being less noble than the metal of the more noble metal layer, the metal filling the convex to form a wiring pattern;

removing the resin layer;

embedding the wiring pattern in an insulating layer; and

removing the conductive support metal foil and the nodule layer by etching to expose the insulating layer and the more noble metal forming an upper end portion of the wiring pattern.

In the fourth process, the conductive support metal foil may have a support resin film on a surface opposite to the surface with the photosensitive resin layer.

The step for embedding the wiring pattern in an insulating layer is preferably performed by applying a resin precursor capable of forming a resin of the insulating layer to a surface of the conductive support metal foil exposed by the removal of the resin layer, and curing the resin precursor.

Also preferably, the step for embedding the wiring pattern in an insulating layer is performed by applying an insulating composite film to a surface of the conductive support metal foil exposed by the removal of the resin layer, the insulating composite film having an insulating resin film and a thermosetting adhesive layer, and heating the insulating composite film to cure the thermosetting adhesive layer while the wiring pattern is embedded in the thermosetting adhesive layer.

Preferably, the fourth process further comprises a step of forming a nodule on a bottom of the wiring pattern to be embedded in the insulating layer.

In the wiring boards according to the invention, the trapezoidal wiring pattern is embedded in the insulating layer while exposing the upper end surface of the upper end portion on the surface of the insulating layer. The wiring pattern embedded in the insulating layer has a trapezoidal cross section in which the cross sectional width is smallest in the upper end surface and gradually increases toward the depth of the insulating substrate. Consequently, the wiring pattern shows very high bond strength to the insulating layer even when the wiring pattern has a pitch of not more than 20 μm. The wiring pattern is not separated from the insulating layer even when an adhesive tape or the like is attached to the upper surface of the wiring pattern and is peeled therefrom.

The processes for manufacturing the wiring board according to the invention do not involve the selective etching of a conductive metal foil for forming a wiring pattern. Therefore, the processes can produce a wiring pattern with a fine pitch such as not more than 20 μm, and eliminate the problems of wires excessively etched to an extremely small cross sectional area and increased electrical resistance in such excessively etched wires.

In the wiring boards of the invention, the main body of the wiring pattern is embedded in the insulating layer, and there is no excessive metal between the wires. Consequently, migration between wires and similar problems are prevented, and insulation between adjacent wires is ensured even when the pitch is small.

The wiring boards of the invention achieve high insulation reliability and stable and highly reliable wiring resistance even when the pitch is very small, for example not more than 20 μm.

### BRIEF DESCRIPTION OF THE DRAWINGS

FIG. 1 is a cross sectional view showing a wiring board according to an embodiment of the invention;

FIG. 2 is a set of sectional views of a board in a process for manufacturing a wiring board according to an embodiment of the invention;

FIG. 3 is a set of sectional views of a board in another process for manufacturing a wiring board according to an embodiment of the invention;

FIG. 4 is a sectional view of a wiring board manufactured by the process illustrated in FIG. 3;

FIG. 5-1 is a set of sectional views of a board in another process for manufacturing a wiring board according to an embodiment of the invention;

FIG. 5-2 is a set of sectional views of a board in the another process for manufacturing a wiring board according to an embodiment of the invention;

FIG. 6 is a sectional view showing an embodiment of a wiring board in which nodules are formed on a lower end portion of a trapezoidal wiring pattern;

FIG. 7 is a sectional view showing another embodiment of a wiring board in which nodules are formed on a lower end portion of a trapezoidal wiring pattern;

FIG. 8-1 is a set of sectional views of a board in another process for manufacturing a wiring board according to an embodiment of the invention;

FIG. 8-2 is a set of sectional views of a board in the another process for manufacturing a wiring board according to an embodiment of the invention;

FIG. 9 is a sectional view showing a wiring board manufactured by the process illustrated in FIG. 8; and

FIG. 10 is a picture of a cross section of a wiring board produced in Example 1 of the present invention.

### PREFERRED EMBODIMENTS OF THE INVENTION

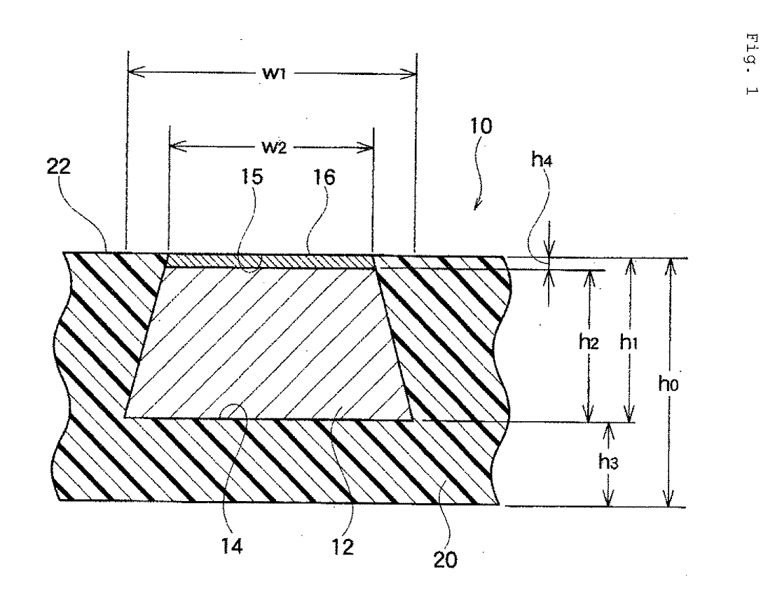

The wiring board according to an embodiment of the present invention will be described with reference to FIG. 1.

As shown in FIG. 1, a wiring in a wiring board according to the present invention includes a main body and an upper end portion. The upper end portion is composed of a metal that is more noble (lower ionization energy) than a metal of the main body.

Referring to FIG. 1, a wiring board 10 includes a wiring pattern 12 in which a cross sectional width W1 of a lower end portion 14 is greater than a cross sectional width W2 of an upper end portion 15 of the wiring pattern 12. As a result, the wiring pattern is substantially trapezoidal in cross section.

A main body 13 of the wiring pattern 12 is composed of a conductive metal, generally copper or a copper alloy. The upper end portion 15 is a metal layer 16 that is more noble (lower ionization energy) than the conductive metal of the main body 13. Examples of such noble metals include gold, platinum, silver and palladium, with gold being preferable. The thickness (h4) of the more noble metal layer is generally 0.01 to 3 μm, preferably 0.01 to 1 μm.

The width W1 of the lower end portion is greater than the width W2 of the upper end portion. The bottom width W1 that represents the line width is generally 4 to 50 μm, preferably 6 to 40 μm. The top width W2 is generally 2 to 40 μm, preferably 4 to 30 μm. In the wiring pattern 12, the ratio of the width W1 of the lower end portion 14 to the width W2 of the upper end portion 15 (W2/W1) is generally 0.1 to 0.9, preferably 0.2 to 0.8. The height (h1) of the trapezoidal wiring is generally 3 to 15 μm, preferably 5 to 10 μm. The height (h4) of the more noble metal layer 16 is generally 0.01 to 3 μm, preferably 0.1 to 1 μm as described above. Therefore, the height (h2) of the main body 13 is generally 2.99 to 12 μm, preferably 4.9 to 9 μm.

The wiring pattern 12 trapezoidal in cross section is embedded in an insulating film 20, and a surface of the more noble metal layer (upper end portion 15) of the wiring pattern 12 is on the same level as a surface 22 of the insulating film 20.

The height (h0) of the insulating film 20 is generally 1.01 to 2.0 times, preferably 1.1 to 1.5 times the height (h1) of the wiring 12, and is generally 3.03 to 30 μm, preferably 5.5 to 15 μm. Therefore, the height (h3) from the lower end portion 14 of the wiring pattern 12 to a lower end of the insulating film 20 is generally 0.03 to 15 μm, preferably 0.5 to 5 μm.

The wiring pattern 10 generally has a pitch of 10 to 100 μm, preferably 15 to 80 μm. According to the present invention, the wiring pattern having this small pitch shows high adhesion to the insulating film because the wiring pattern is embedded in the insulating film and has a substantially trapezoidal cross section as shown in FIG. 1.

The wiring board may be manufactured by a first process as described below.

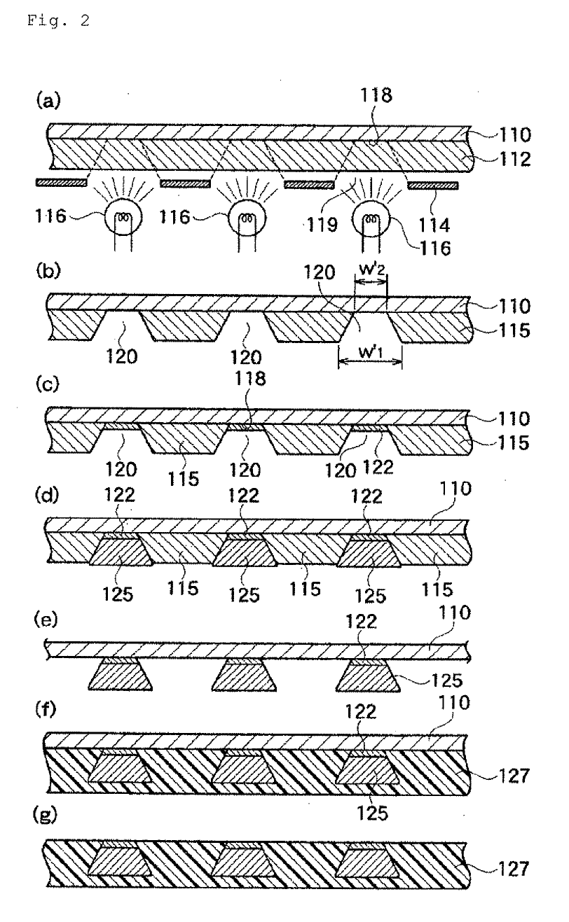

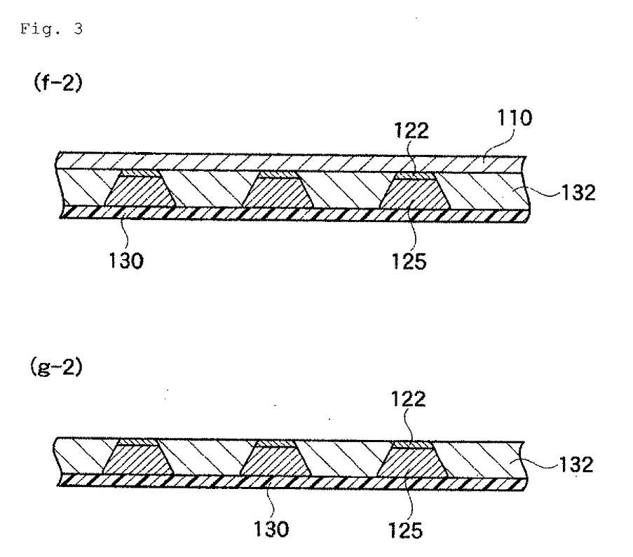

In the first process, a conductive support metal foil 110 is provided, and a photosensitive resin layer 112 is formed on a surface of the conductive support metal foil 110 as shown in FIG. 2(a). The conductive support metal foil 110 may be a metal foil which has conductivity for electroplating and which can be removed by etching in a later step. Examples of the conductive support metal foils 110 include copper foils and aluminum foils, with the copper foils being preferable in view of the properties of being etched. The copper foils include electrodeposited copper foils and rolled copper foils. In the invention, any conductive metal foils may be used. The thickness of the conductive support metal foil 110 may be determined appropriately, and is generally 3 to 18 μm, preferably 6 to 12 μm. In the invention, the conductive support metal foil 110 is usually a single foil. When the conductive support metal foil 110 is thin, a resin support layer (not shown) may be provided on a surface of the metal foil opposite to the surface on which the photosensitive resin layer 112 will be formed.

The photosensitive resin layer 112 is formed on a surface of the conductive support metal layer 110. The photosensitive resin layer 112 should be positive. The photosensitive resin layer 112 is generally 3 to 20 μm, preferably 6 to 18 μm in thickness. The photosensitive resin layer 112 may be formed by applying a photosensitive resin with a known device such as a roll coater, a doctor blade coating system, a spin coater or a dip coater. The photosensitive resin thus applied may be cured by heating at temperatures of 100 to 130° C. for 2 to 3 minutes to give a photosensitive resin layer 112.

Subsequently, as shown in FIG. 2(a), a desired exposure pattern 114 is located above the surface of the photosensitive resin layer 112. The photosensitive resin layer 112 is exposed using an exposure apparatus 116, and a latent image is developed. Consequently, the cured resin forms a pattern 115 as shown in FIG. 2(b).

The photosensitive resin layer is exposed in a manner such that a bottom opening 118 facing the conductive support metal foil 110 will have a width W′2 smaller than a width W′1 of a surface opening 119. For example, an exposure apparatus with a non-telecentric lens (maximum incident angle of principal rays: ± not less than 2°) may apply UV lights having i line, h line and g line to create the bottom opening 118 narrower than the surface opening 119. It is needless to say that the photoresist used herein is positive.

The photosensitive resin layer 112 may be exposed using exposure apparatus FP-70SAC (manufactured by USHIO INC.) capable of emitting energy beams with dominant wavelengths of 365 nm (i line), 405 nm (h line) and 436 nm (g line), at a dose of 600 to 1300 mJ/cm². The exposed resin layer 112 is soaked in a developing solution to produce the resin pattern 115 as shown in FIG. 2(b). The pattern 115 provides a groove 120 in which a wiring will be formed. The bottom of the groove 120 is the bottom opening 118 formed in the resin pattern 115, and the bottom opening 118 is closed by contact with the conductive support metal foil 110. The other opening of the groove 120 is the surface opening 119. A conductor is deposited in the groove 120 to form a wiring.

After the pattern 115 is formed and thereby the groove 120 is created as illustrated in FIG. 2(b), a noble metal deposit layer 122 is formed on the conductive support metal foil 110 exposed from the bottom opening 118 of the groove 120. The noble metal deposit layer 122 is composed of a metal that is more noble (lower ionization energy) than a metal of a wiring main body that will be deposited to fill the groove 120. When the main body is copper or a copper alloy, the more noble metal may be gold, platinum, silver or an alloy of these metals. In the invention, gold is particularly preferable. Controlling the thickness of gold deposit layer is easy, and the more noble metal deposit layer 122 composed of gold is not corroded by an etching solution used in a later step and prevents the wiring from being corroded by the etching solution.

The gold deposit layer 122 may be formed under plating conditions of Dk of 0.1 to 1 A/dm², a temperature of 60 to 70° C., and a plating time of 0.2 to 6 minutes. Under such conditions, the gold deposit layer 122 as shown in FIG. 2(c) may be formed to a thickness of 0.01 to 3 μm, preferably 0.1 to 1 μm.

After the more noble metal deposit layer 122 is formed in the bottom opening 118 of the groove 120, a metal that is less noble (higher ionization energy) than the metal of the more noble metal deposit layer is deposited in the groove 120. In the invention, the less noble metal is usually copper or a copper alloy. Specifically, the more noble metal deposit layer 122 is electroplated with a commercially available copper plating solution under plating conditions of Dk of 1 to 3 A/dm², a temperature of 17 to 24° C., and a plating time of 10 to 20 minutes. Under such conditions, a dense copper deposit layer as shown in FIG. 2(d) may be formed in the groove 120. The copper is deposited to a thickness substantially equal to the depth of the groove 120. Consequently, the groove 120 is filled with the copper, whereby a wiring pattern 125 is formed. Thereafter, the resin pattern 115 is removed. The resin pattern 115 may be easily removed with an aqueous alkali metal hydroxide solution adjusted to a concentration of about 10%.

The alkali cleaning removes the pattern 115 as shown in FIG. 2(e).

Removing the pattern 115 results in a structure in which the wiring pattern 125 is bonded to the surface of the conductive support metal foil 110 via the more noble metal deposit layer 122. The wiring pattern 125 has a trapezoidal cross section.

Subsequently, an insulating layer 127 is formed on the surface of the conductive support metal foil 110 and the wiring pattern 125.

The insulating layer 127 may be formed by applying a precursor of an insulating resin to a thickness such that the wiring pattern 125 is embedded therein, and curing the precursor by heating at a predetermined temperature. As an example, referring to FIG. 2(f), a solution for an insulating layer such as a methylpyrrolidone solution of polyamic acid may be applied on the conductive support metal foil 110 to a thickness such that the wiring pattern 125 is embedded therein, for example to a thickness (μm) about 1.01 to 1.8 times the height (h1) of the wiring pattern 125; and the coating may be heated to evaporate the solvent and to cure the resin component for forming the insulating layer. With a polyimide precursor, the heating temperature is generally in the range of 250 to 500° C., preferably 300 to 400° C., and the heating time is generally 120 to 360 minutes, preferably 180 to 240 minutes.

The insulating layer (cured resin) 127 formed as described above includes the trapezoidal wiring pattern 125 as illustrated in FIG. 2(f).

After the insulating layer 127 is formed, the conductive support metal foil 110 is removed by etching. The conductive support metal foil 110 is generally an electrodeposited copper foil as described above, and can therefore be removed with a copper etching solution containing cupric chloride, hydrogen peroxide and hydrochloric acid. Such etching solution dissolves the conductive support metal foil 110 to expose the cured insulating layer 127 in areas without the wiring pattern and to expose the more noble metal deposit layer 122 (upper end portion of the wiring pattern) in areas where the wiring pattern 125 is formed, as illustrated in FIG. 2(g). The more noble metal deposit layer 122 is resistant to being etched by the etching solution. Therefore, etching can completely remove the conductive support metal foil 110 covering the insulating layer 127 and the more noble metal deposit layer 122, whilst the more noble metal deposit layer 122 covering the wiring main body is exposed on the surface of the insulating layer 127 as shown in FIG. 2(g). Below the more noble metal deposit layer 122, the main body of the trapezoidal wiring pattern 125 is embedded in the insulating layer 127. The more noble metal deposit layer 122 represents a shorter side of the trapezoid.

Because the conductive support metal foil 110 covering neighboring wires has been removed by etching as described above, there is no metal on the surface of the insulating layer 127 adjacent to the more noble metal deposit layer 122. Accordingly, the insulating layer does not suffer migration, and short circuits between neighboring wires are avoided. Furthermore, the wiring pattern 125 has a trapezoidal cross section in which the width thereof increases with depth in which the pattern is embedded in the insulating layer. Consequently, it is substantially impossible that the trapezoidal wiring pattern 125 is pulled out from the insulating layer 127. Thus, the wiring pattern 125 shows very high adhesion to the insulating layer 127.

As described above, the process of the present invention can produce a fine wiring pattern by other than etching a metal layer into a wiring pattern, and is therefore free of a problem of excessively etched wires. Accordingly, the wiring pattern can be designed in small pitches without resulting in an excessively reduced line width.

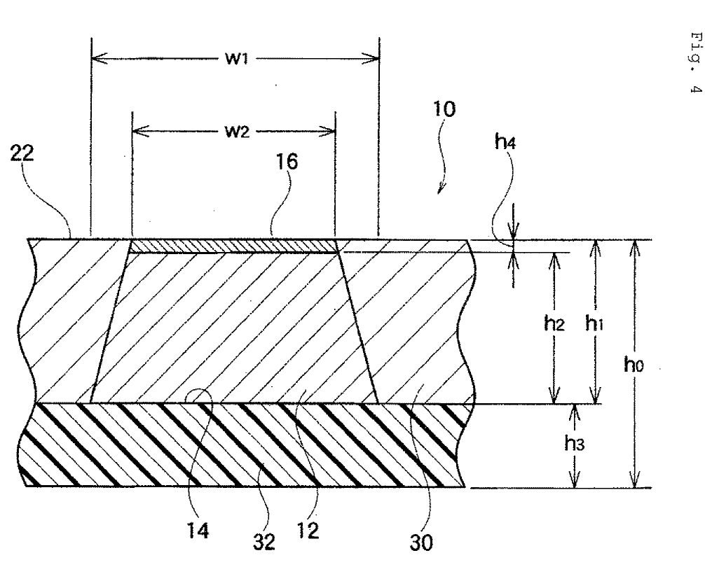

In the process of the invention, a step shown in FIG. 3(f-2) may be performed after the wiring pattern 125 is produced as illustrated in FIG. 2(e). An insulating composite film has an insulating resin film 130 and a thermosetting adhesive layer 132. The insulating composite film is pressure bonded to the wiring pattern 125 and the thermosetting adhesive layer 132 is cured by heating. Consequently, the wiring pattern 125 is embedded in the cured layer 132. Subsequently, as shown in FIG. 3(g-2), the conductive support metal foil 110 is etched as described hereinabove to expose the cured layer 132.

In the figure, the thermosetting adhesive layer 132 is formed to a thickness equal to or slightly greater than the height (h1 in FIG. 4) of the wiring pattern 125 so that the wiring pattern 125 can be completely embedded therein. Such thickness illustrated in the figure is not restrictive, and the thickness of the thermosetting adhesive layer 132 should be at least such that a lower end portion of the wiring pattern 125 can be fixed. In general, the thickness may be such that at least 20%, preferably not less than 50% of the slope of the trapezoidal wiring pattern 125 from the lower end surface can be embedded in the adhesive layer. However, if the slope of the trapezoidal wiring pattern 125 is partly exposed from the cured resin layer 132, such exposed slope of the wiring pattern is brought into contact with an etching solution in the subsequent step in which the conductive support metal foil 110 is etched. Such exposed slope of the wiring pattern 125 will be corroded by contact with the etching solution and will be reduced in line width. Therefore, when the conductive support metal foil 110 has a large thickness and will require long contact with the etching solution for complete dissolution, the cured resin layer 132 preferably covers the entire slope of the wiring pattern 125.

Examples of the adhesives for the thermosetting adhesive layer include epoxy adhesives, urethane adhesives, acrylic adhesives and polyimide adhesives. Examples of the insulating films bonded to the wiring pattern via the thermosetting adhesive layer 132 include polyimide films, polyetherimide films and liquid crystal polymers. The thickness (h3) of the insulating film is generally in the range of 12.5 to 75 μm, preferably 25 to 50 μm.

The wiring board manufactured as described above has a cross sectional structure illustrated in FIG. 4. The cross sectional structure is identical to that shown in FIG. 1, except that the trapezoidal wiring pattern 12 is embedded in a cured layer 30 formed from the thermosetting adhesive, and that an insulating film 32 is under the lower end portion 14 of the main body of the wiring pattern 12. Accordingly, the heights h0 to h3 of the wiring board and widths W1 and W2 of the wiring pattern in FIG. 4 are the same as in FIG. 1.

Alternatively, the wiring board according to the invention may be manufactured by a second process as described below. In the second process, a photosensitive resin layer is formed on a surface of a conductive support metal foil; the photosensitive resin layer is exposed and developed to form a groove for forming a wiring pattern, the groove having a bottom opening facing the conductive support metal foil, the bottom opening having a width smaller than that of a surface opening; a conductive metal is deposited on the conductive support metal foil exposed from the bottom opening of the groove, the conductive metal being more noble than a metal of the conductive support metal foil; and a conductive metal is deposited on the noble conductive metal, the conductive metal being less noble than the noble conductive metal and filling the groove to form a wiring pattern. These steps are performed in the same manner as in the first process. In the second process, after the less noble conductive metal is deposited on the noble conductive metal, the following steps are performed:

(A) depositing a nodule layer on a bottom of the wiring pattern;

removing the resin layer;

(B) embedding the wiring pattern and the nodule layer in an insulating layer; and

removing the conductive support metal foil by etching to expose the insulating layer and the more noble metal forming an upper end portion of the wiring pattern.

The steps (A) and (B) are the same as in a third process which will be described below, and details in these steps are described in the third process.

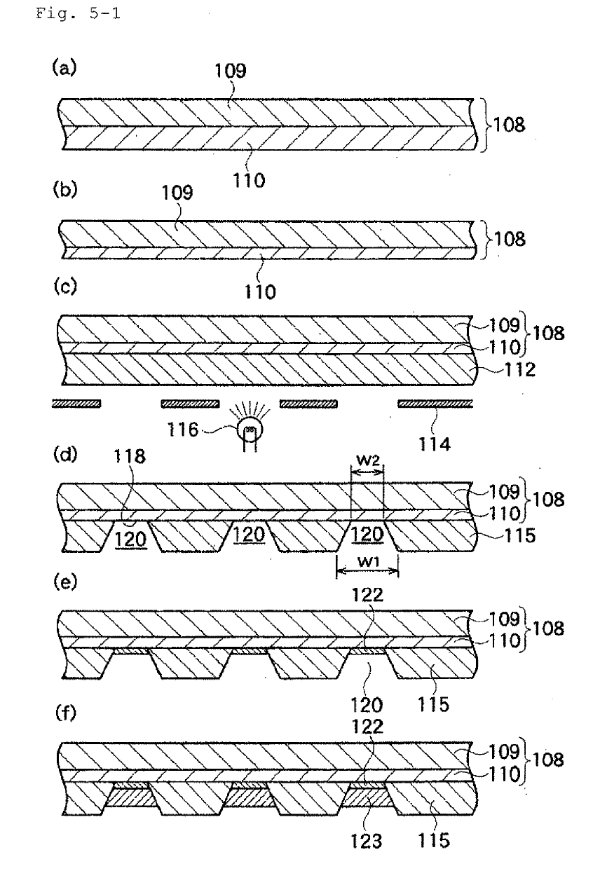

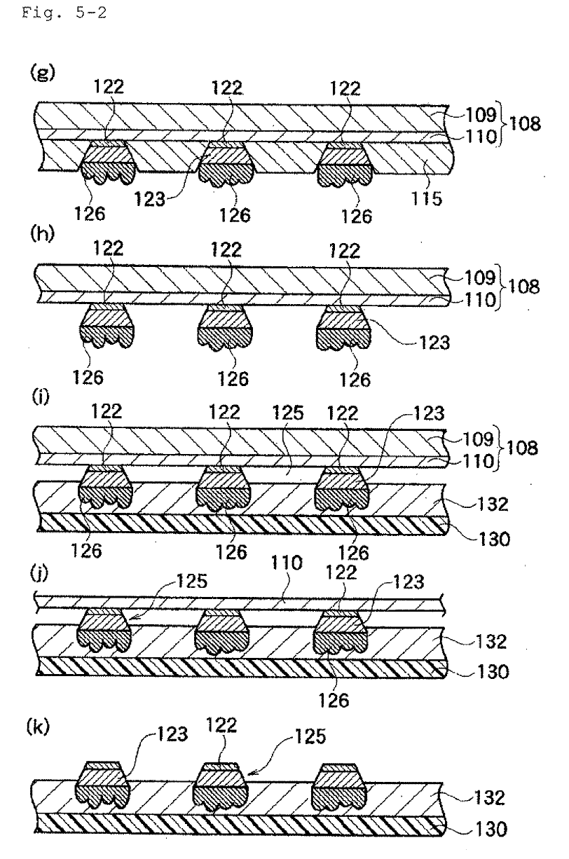

Alternatively, the wiring board according to the present invention may be manufactured by a third process as illustrated in FIG. 5. FIG. 5 is a set of sectional views of a board in another process for manufacturing a wiring board according to an embodiment of the invention.

In the embodiment shown in FIG. 2, the conductive support metal foil 110 is used as it is. In this embodiment of FIG. 5, a conductive support metal foil 110 is preliminarily reduced in thickness by half etching or the like in order to shorten the time required for the contact of the conductive support metal foil 110 with the etching solution. Therefore, the conductive support metal foil 110 and a support resin film 109 are laminated together beforehand into a laminated film 108 as shown in FIG. 5(a). The conductive support metal foil 110 and the support resin film 109 may be laminated with or without an adhesive.

The support resin film 109 may be made of any material without limitation as long as it can support the conductive support metal foil 110. Examples thereof include PET (polyethylene terephthalate) films, polyimide films and polyolefin films. The thickness of the support resin film 109 is not particularly limited and is suitably in the range of 10 to 200 μm to permit easy handling of the conductive support metal foil 110.

The conductive support metal foil 110 of the laminated film 108 is brought into contact with a copper etching solution containing cupric chloride, hydrochloric acid and hydrogen peroxide. The contacting method is not particularly limited, and spray etching is preferable because it can etch the conductive support metal foil 110 uniformly.

By the half etching, the thickness of the conductive support metal foil 110 is usually reduced to 0.1 to 5 μm, preferably 0.2 to 3 μm. In the process of the invention, the conductive support metal foil 110 works as a conductive member and its strength is ensured by the support resin film 109. Therefore, it is advantageous that the conductive support metal foil 110 is reduced in thickness as described above in order to shorten the contact time required for the metal foil to be removed with the etching solution in a later step.

FIG. 5(b) illustrates the laminated film 108 in which the conductive support metal foil 110 is half etched.

Subsequently, a photosensitive resin layer 112 is formed on the surface of the conductive support metal foil 110 of the laminated film 108. The photosensitive resin layer 112 should be positive. The photosensitive resin layer 112 is generally 3 to 20 μm, preferably 6 to 18 μm in thickness. The photosensitive resin layer 112 may be formed by applying a photosensitive resin with a known device and curing the resin by heating at temperatures as described above for a predetermined time.

The photosensitive resin layer 112 shown in FIG. 5(c) has been cured by such heating.

Subsequently, as shown in FIG. 5(c), a desired exposure pattern 114 is located above the surface of the photosensitive resin layer 112. The photosensitive resin layer 112 is exposed using an exposure apparatus 116, and a latent image is developed. Consequently, the cured resin forms a pattern 115 as shown in FIG. 5(d).

The positive photosensitive resin layer 112 may be exposed using an exposure apparatus with a non-telecentric lens capable of emitting lights having i line, h line and g line, and thereby a bottom opening 118 facing the surface of the conductive support metal foil 110 has a width W′2 smaller than a width W′1 of a surface opening 119. As an example, the photosensitive resin layer 112 may be exposed to lights emitted from exposure apparatus FP-70SAC-02 (manufactured by USHIO INC.) that is located at a certain distance from the exposure photomask 114 and the photosensitive resin layer 112. The resultant bottom opening 118 will be narrower than the surface opening 119.

The exposure conditions may be the same as described above. The exposed resin layer 112 is soaked in a developing solution to produce the resin pattern 115 as shown in FIG. 5(d). The pattern 115 provides a groove 120 in which a wiring will be formed.

Subsequently, a metal is deposited in the groove 120 to produce a wiring pattern.

Specifically, a noble metal deposit layer 122 is formed on the conductive support metal foil 110 exposed from the bottom opening 118 of the groove 120. The noble metal deposit layer 122 is composed of a metal that is more noble (lower ionization energy) than a metal of a wiring main body that will be deposited to fill the groove 120. When the wiring main body is copper or a copper alloy, the more noble metal may be gold, platinum, silver or an alloy of these metals. In the invention, gold is particularly preferable. Controlling the thickness of gold deposit layer is easy, and the more noble metal deposit layer 122 composed of gold is not corroded by an etching solution used in a later step and prevents the wiring from being corroded by the etching solution.

The gold deposit layer 122 may be formed under plating conditions of Dk of 0.1 to 1 A/dm², a temperature of 60 to 70° C., and a plating time of 0.2 to 6 minutes. Under such conditions, the gold deposit layer 122 as shown in FIG. 5(e) may be formed to a thickness of 0.01 to 3 μm, preferably 0.1 to 1 μm.

After the more noble metal deposit layer 122 is formed in the bottom opening 118 of the groove 120, a metal that is less noble (higher ionization energy) than the metal (e.g., gold) of the more noble metal deposit layer is deposited in the groove 120. In the invention, the less noble metal is usually copper or a copper alloy. Specifically, the more noble metal deposit layer 122 is electroplated with a commercially available copper plating solution under plating conditions of Dk of 1 to 3 A/dm², a temperature of 17 to 24° C., and a plating time of 10 to 20 minutes. Under such conditions, a dense copper deposit layer as shown in FIG. 5(f) maybe formed in the groove 120. The dense copper deposit layer is a main body 123 of the wiring. The thickness of the main body 123 may be substantially equal to the thickness of the pattern 115. However, in view of the subsequent step in which a nodule layer is deposited on the main body 123, it is preferable that the main body 123 is slightly thinner than the pattern 115, approximately 80 to 99% of the thickness of the pattern 115.

The step (A) for depositing a nodule layer on a bottom of the wiring pattern will be described.

After the wiring main body 123 is produced, a nodule layer 126 is formed on the lower end surface of the main body 123 as illustrated in FIG. 5(g). The nodule layer 126 is generally a dendritic metal deposit 0.1 to 15 μm in height, and may be formed by electroplating. The nodule layer 126 anchors the wiring to an insulating layer, and is not necessarily formed of the same metal as the wiring main body 123. Preferably, the nodule layer 126 is formed integrally with the main body 123. In the invention, the wiring main body 123 is generally composed of copper or a copper alloy, and therefore the nodule layer 126 is preferably formed of copper or the copper alloy.

When the nodule layer 126 is formed by depositing copper or a copper alloy, general plating conditions are a plating current density of 3 to 30 A/dm², a copper ion concentration in plating solution of 1 to 50 g/l, a plating temperature of 20 to 60° C., and a plating time of 5 to 600 seconds. Suitable examples of copper plating baths for use herein include copper sulfate plating baths and copper pyrophosphate plating baths. Under the above conditions, copper is dendritically deposited. The thickness of the nodule layer 126 is generally 0.1 to 15 μm, preferably 1 to 10 μm. On the nodule layer thus formed, lumps and a covering layer may be deposited as required. The lumps refer to fine metal particles deposited on the nodule layer, and the covering layer covers such fine metal particles and fixes the particles to the nodule layer. When the nodule layer is copper or a copper alloy, the lumps and the covering layer are generally deposited using copper or the copper alloy.

After the nodule layer 126 is formed, the pattern 115 is removed. The cured resin pattern 115 may be easily removed with an aqueous alkali metal hydroxide solution adjusted to a concentration of about 10%.

FIG. 5(h) shows a structure resulting from the removal of the pattern 115.

This structure has a plurality of wirings in which the wiring main body 123 is bonded to the conductive support metal foil 110 via the more noble metal deposit layer 122, and the nodule layer 126 is formed under the main body 123. The wiring has a trapezoidal cross section in which the cross sectional width of the more noble metal deposit layer 122 is smaller than that of the lower end portion of the main body 123.

The step (B) for embedding then wiring pattern and the nodule layer in an insulating layer will be described.

Subsequently, the wiring and the nodule layer 126 are embedded in an insulating layer.

The insulating layer for embedding the wiring pattern and the nodule layer may be formed by applying a resin precursor capable of forming a resin of the insulating layer, to the conductive support metal foil; and curing the precursor to produce the insulating resin layer in which the wiring pattern and the nodule layer are embedded. Alternatively, the insulating layer may be formed by applying an insulating composite film having an insulating resin film and a thermosetting resin layer, to the wiring pattern such that the nodule layer and at least part of the wiring pattern are embedded in the thermosetting resin layer; and heating the composite film to cure the thermosetting resin layer.

FIG. 5(i) shows an embodiment in which an insulating composite film is used which has an insulating resin film 130 and a thermosetting resin layer 132.

The thickness of the thermosetting adhesive layer 132 may be substantially equal to the thickness of the wiring pattern 125 so that the wiring pattern 125 can be embedded therein. Such thickness is preferable because the embedded wiring pattern 125 will not be brought into contact with and therefore will not be corroded by the etching solution used for etching the conductive support metal foil 110. However, because the conductive support metal foil 110 has been half etched to a reduced thickness and will not require a long contact time with the etching solution for dissolution, part of the wiring pattern 125 may be exposed from the thermosetting resin layer 132. Such exposed slope of the wiring pattern 125 will release a very trace amount of the metal (e.g., copper or copper alloy) during such short contact with the etching solution. However, if a large proportion of the wiring pattern 125 is exposed, the wiring pattern 125 often fails to achieve sufficient bond strength to the thermosetting adhesive layer 132. Accordingly, the insulating composite film 130 suitably has the thermosetting resin layer 132 with a thickness such that at least 20%, preferably not less than 50% of the slope of the trapezoidal wiring pattern from the lower end surface can be embedded in the cured resin layer 132.

After at least part of the wiring pattern 125 is embedded in the thermosetting adhesive layer 132, the thermosetting adhesive layer 132 is cured by heating. Examples of the adhesive resins for the thermosetting adhesive layer include those described hereinabove. The curing temperature and time are as described above.

After the thermosetting adhesive layer 132 is cured, the support resin film 109 of the laminated film 108 is released. The bond strength between the support resin film 109 and the conductive support metal foil 110 is not so high that the support resin film 109 can be separated from the conductive support metal foil 110 without any special device.

Releasing the support resin film 109 exposes the conductive support metal foil 110.

Subsequently, the conductive support metal foil 110 is removed by contact with an etching solution. The conductive support metal foil 110 is generally an electrodeposited copper foil. As described hereinabove, the conductive support metal foil 110 is laminated to the support resin film 109 and is half etched to a very small thickness. Therefore, the conductive support metal foil 110 can be removed by contact with an etching solution in a very short time. For example, the conductive support metal foil may be removed by being brought into contact with an etching solution containing cupric chloride, hydrochloric acid and hydrogen peroxide at 35 to 45° C. and for 8 to 60 seconds, preferably 15 to 50 seconds.

The half-etched conductive support metal foil can be removed completely in a short time by contact with the etching solution under the conditions as described above. The upper end portion of the wiring pattern is the more noble metal deposit layer (preferably gold deposit layer) which is immediately under the conductive support metal foil. The more noble metal deposit layer is resistant to being etched by the etching solution and prevents the wiring pattern from being reduced in thickness by contact with the etching solution. If the trapezoidal wiring pattern is not completely embedded in the insulating layer, the exposed slope of the wiring pattern is brought into contact with the etching solution and is etched to some degree. However, the contact time with the etching solution is very short and the wiring pattern is not etched to such an extent that characteristics of the wiring pattern are deteriorated.

The more noble metal deposit layer such as gold deposit layer representing the upper end portion of the wiring pattern has a flat surface. When a liquid crystal display device is mounted on the wiring board according to the invention, an electrical connection can be established using a conventional anisotropic conductive adhesive. Because terminals in the wiring board are gold or the like, a stable electrical connection can be established.

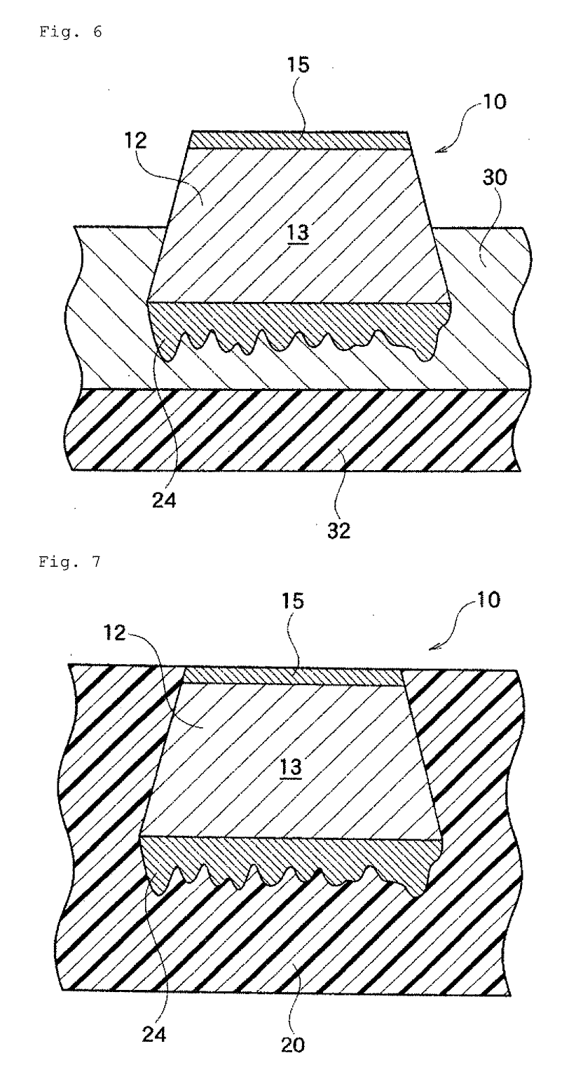

As illustrated in FIGS. 6 and 7, a nodule layer 24 is formed on the lower end surface of the trapezoidal wiring pattern 12. The nodule layer 24 is firmly fixed in the insulating layer and firmly anchors the wiring pattern 12 to the insulating layer. Furthermore, the wiring pattern 12 is configured such that the lower end portion is wider than the upper end portion, and at least the lower end portion of the wiring pattern 12 is embedded in the insulating layer. According to this structure, there is no possibility that the wiring pattern 12 is separated from the insulating layer.

The process according to the invention does not involve the selective etching of a copper foil to form a wiring pattern. Therefore, the process can produce a wiring pattern with a fine pitch such as not more than 20 μm, and eliminates the problems of excessively etched wiring patterns and consequent substantially ineffective wirings. Moreover, the main body of the trapezoidal wiring pattern is embedded in the insulating layer, and the wiring pattern is prevented from being etched to an excessively small width. The wiring has a uniform thickness and the wiring resistance is not varied within the wiring. Because the wiring pattern is embedded in the insulating layer and there is no metal between the wires, migration between wires are prevented, and the wiring board shows very high insulation properties.

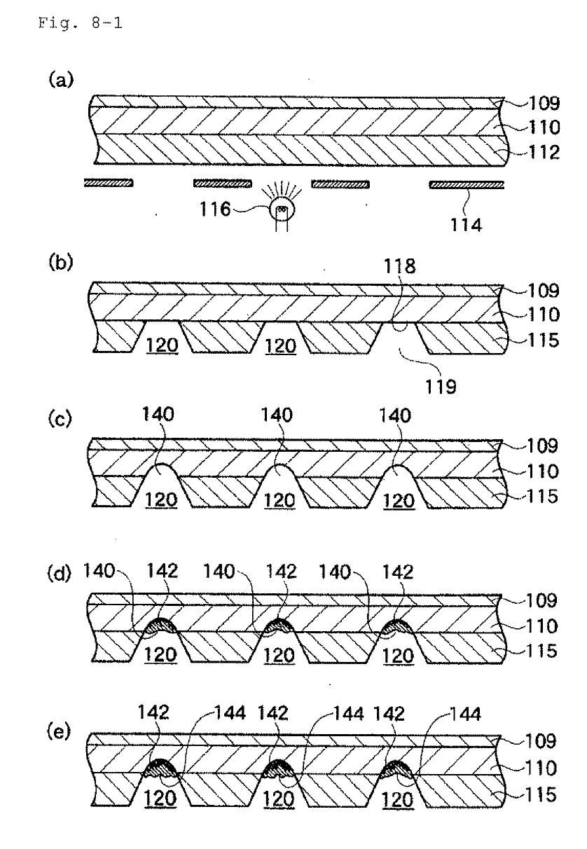

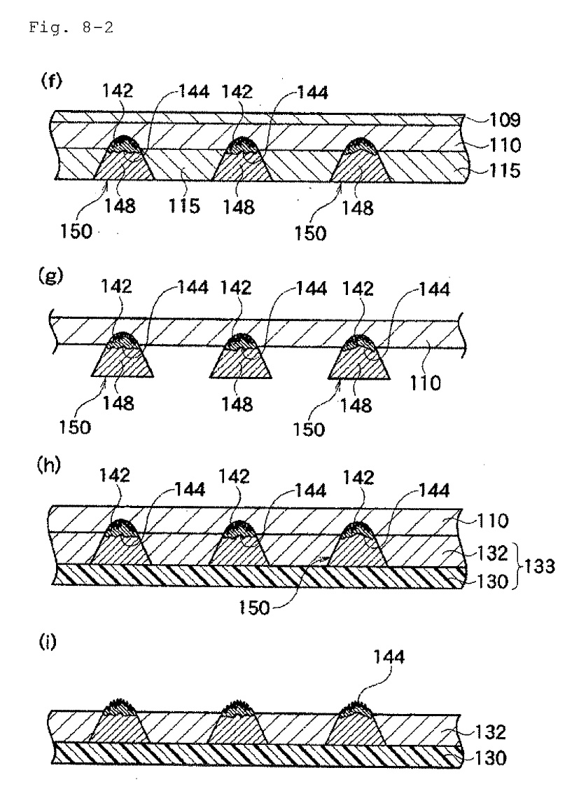

Further alternatively, the wiring board according to the present invention may be manufactured by a fourth process as illustrated in FIG. 8. A relatively thick conductive support metal foil 110 is coated with a photosensitive resin layer 112. In this embodiment, a resin layer 109 may be formed on the surface of the conductive support metal foil 110 opposite to the photosensitive resin layer 112 to protect the conductive support metal foil 110. The resin layer 109 may be formed by applying a resin composition or by transferring a resin layer formed on a film. The resin layer 109 prevents the back surface of the conductive support metal foil 110 from being etched when the conductive support metal foil 110 is partly etched.

After the photosensitive resin layer 112 is formed on the conductive support metal foil 110, an exposure pattern 114 is located. The photosensitive resin layer 112 is exposed using an exposure apparatus 116, and a latent image is developed as described hereinabove.

The exposure and development result in a structure shown in FIG. 8(b). As illustrated, a pattern 115 forms a groove 120 in which a bottom opening 118 facing the conductive support metal foil 110 has a width smaller than a width of a surface opening 119.

In this embodiment, the conductive support metal foil 110 exposed from the pattern 115 is half etched with an etching solution using the pattern 115 as a mask. Consequently, a recess 140 is formed in the conductive support metal foil 110. The recess 140 has a depth that is generally 30 to 80%, preferably 40 to 70% relative to the thickness of the conductive support metal foil 110. Specifically, the depth of the recess 140 is in the range of 4 to 16 μm, preferably 6 to 14 μm. The recess 140 formed in the conductive support metal foil 110 is illustrated in FIG. 8 (c).

Subsequently, a nodule layer 142 is formed on the recess 140.

The nodule layer 142 is generally a dendritic metal deposit 0.1 to 15 μm in height, and may be formed by electroplating. The nodule layer 142 may be any metal without particular limitation, and is preferably the same metal as the conductive support metal foil 110. Therefore, because the conductive support metal foil 110 is preferably copper or a copper alloy in the invention, the nodule layer 142 is preferably copper or the copper alloy.

When the nodule layer 142 is formed by depositing copper or a copper alloy, general plating conditions are a plating current density of 3 to 30 A/dm², a copper ion concentration in plating solution of 1 to 50 g/l, a plating temperature of 20 to 60° C., and a plating time of 5 to 600 seconds. Suitable examples of copper plating baths for use herein include copper sulfate plating baths and copper pyrophosphate plating baths. Under such conditions, copper (nodule layer 142) is dendritically deposited in the recess 140 of the conductive support metal foil 110. The thickness of the nodule layer 142 is generally 0.1 to 15 μm. preferably 1 to 10 μm. On the nodule layer 142 thus formed, lumps and a covering layer may be deposited as required. The lumps refer to fine metal particles deposited on the nodule layer 142, and the covering layer covers such fine metal particles and fixes the particles to the nodule layer 142. When the nodule layer is copper or a copper alloy, the lumps and the covering layer are generally deposited using copper or the copper alloy. The nodule layer and the optional lumps and covering layer are electrodeposited in the recess 140 of the conductive support metal foil 110, and are not formed on the pattern 115 having no conductivity.

After the nodule layer and the optional lumps and covering layer are deposited in. the recess 140 of the conductive support metal foil 110, a metal layer 144 is deposited in the recess 140 using a metal that is more noble than a metal of a wiring main body which will be formed in the groove 120. FIG. 8(e) illustrates the more noble metal deposit layer 144 that is gold.

The more noble metal deposit layer 144 is formed by electroplating to cover the nodule layer 142 and the optional lumps and covering layer in the recess 140 of the conductive support metal foil 110. In the case where the more noble metal deposit layer 144 is gold, the thickness thereof is generally 0.1 to 1 μm, preferably 0.2 to 0.8 μm. The more noble metal deposit layer 144 is deposited along the surface of the nodule layer 142 and the optional lumps and covering layer. Therefore, the more noble metal deposit layer 144 reproduces the unevenness of the nodule layer 142 and the optional lumps and covering layer.

In the case of the more noble metal deposit layer 144 which is gold, the gold may be deposited under plating conditions of Dk of 0.1 to 1 A/dm², a temperature of 60 to 70° C., and a plating time of 0.2 to 6 minutes.

After the more noble metal deposit layer 144 is formed, the groove 120 is filled with a metal that is less noble than the metal of the more noble metal deposit layer 144, thereby forming a wiring main body 148 as shown in FIG. 8(f). When the more noble metal deposit layer 144 is gold, the less noble metal is generally copper or a copper alloy.

The less noble metal deposit layer (main body) 148 may be formed by electrodepositing copper or a copper alloy to fill the groove 120.

The less noble metal has higher ionization energy than the metal of the more noble metal deposit layer, such as gold. The less noble metal in the invention is generally copper or a copper alloy. Specifically, the more noble metal deposit layer 144 is electroplated with a commercially available copper plating solution under plating conditions of Dk of 1 to 3 A/dm², a temperature of 17 to 24° C., and a plating time of 10 to 20 minutes. Under such conditions, a dense copper deposit layer as shown in FIG. 8(f) may be formed in the groove 120. The copper is deposited to a thickness substantially equal to the depth of the groove 120. Consequently, the groove 120 is filled with the copper, whereby a wiring pattern 150 is formed. The recess in the conductive support metal foil 110 has a cross sectional width which is smaller than the surface opening 119 in the pattern 115. Consequently, the wiring pattern 150 has a trapezoidal cross section in which the upper end portion forms an arc.

Although not shown in FIG. 8, a nodule layer may be formed on the lower end surface of the wiring pattern 150 as described hereinabove.

After the wiring pattern 150 is formed, the resin layer 109 and the pattern 115 are removed. The bond strength between the resin layer 109 and the conductive support metal foil 110 is not so high that the resin layer 109 can be reeled from the conductive support metal foil 110 without difficulty. Releasing the resin layer 109 exposes the conductive support metal foil 110.

Meanwhile, the pattern 115 is firmly bonded to the conductive support metal foil 110 so that it will not be separated even by vigorous contact with various kinds of etching solutions. Therefore, separating the pattern 115 is difficult with a physical method and requires a releasing agent. The releasing agent may be an aqueous alkali metal hydroxide solution adjusted to a concentration of about 10%. For example, the pattern 115 may be removed by being soaked in a 10% aqueous sodium hydroxide solution for about 0.1 to 10 minutes.

FIG. 8(g) shows a structure resulting from the removal of the resin layer 109 and the pattern 115. In the recess formed in one surface of the conductive support metal foil 110, the nodule layer 142, the optional lumps and covering layer, and the more noble metal deposit layer 144 are formed. The main body 148 (e.g., copper deposit) of the wiring pattern 150 is formed on the conductive support metal foil via the above layers in the recess. The wiring pattern has a trapezoidal cross section in which the cross sectional width of the upper end portion is smaller than that of the lower end portion.

Subsequently, the wiring pattern 150 extending from the conductive support metal foil 110 is embedded in an insulating layer as shown in FIG. 8(h).

The insulating layer for embedding the wiring pattern 150 may be formed by applying a resin precursor capable of forming a resin of the insulating layer, to the conductive support metal foil; and curing the precursor to produce the insulating resin layer in which the wiring pattern 150 is embedded. Alternatively, the insulating layer may be formed by applying an insulating composite film having an insulating resin film and a thermosetting resin layer, to the wiring pattern such that at least part of the wiring pattern 150 is embedded in the thermosetting resin layer; and heating the composite film to cure the thermosetting resin layer.

FIG. 8 shows an embodiment in which the insulating layer is formed by applying an insulating composite film 133 having an insulating resin film 130 and a thermosetting resin (thermosetting adhesive) layer 132 such that the wiring pattern 150 is embedded in the thermosetting adhesive layer 132; and heating the composite film to cure the thermosetting adhesive layer 132. Specifically, referring to FIG. 8(h), the insulating composite film 133 has the insulating resin film 130 such as a polyimide film and the thermosetting adhesive layer 132. The insulating composite film 133 is applied to the surface of the conductive support metal foil 110 on which the wiring pattern 150 is formed. Consequently, the wiring pattern 150 is embedded in the thermosetting adhesive layer 132. The insulating resin film 130 is generally 12.5 to 75 μm, preferably 25 to 50 μm in thickness and may be a polyimide film, a polyetherimide film or a liquid crystal polymer film. The thermosetting adhesive layer 132 is generally 5 to 50 μm, preferably 9 to 25 μm in thickness and may be an epoxy adhesive layer or a polyimide adhesive layer. The thermosetting adhesive layer 132 is laminated on one surface of the insulating resin film 130. Prior to the application, the thermosetting adhesive layer 132 is semi-cured. Heating can soften the thermosetting adhesive layer to an extent such that the wiring pattern 150 can enter into the adhesive layer. While the thermosetting adhesive layer 132 is softened by heating and is compressed against the wiring pattern 150 to include the wiring pattern within the adhesive layer, the thermosetting adhesive layer is cured by the heat. The heating temperature may vary depending on the type of the thermosetting resin used. For an epoxy adhesive, the heating temperature is generally 180 to 200° C., the pressure is generally 2 to 6 kg/cm and the heating time is generally 1 to 2 minutes.

When the thermosetting adhesive layer 132 is softened by heating and is compressed against the wiring pattern 150, the layer includes the wiring pattern therewithin and usually comes into contact with the lower end surface of the conductive support metal foil 110 In the wiring pattern 150 as shown in FIG. 8(g), the more noble metal deposit layer 144 is found in the conductive support metal foil 110, and the slope of the wiring pattern 150 below the more noble metal deposit layer is exposed. Specifically, this exposed part is the main body which is copper or a copper alloy.

The exposed slope of the wiring pattern 150 is covered with the thermosetting adhesive layer 132 when the softened thermosetting adhesive layer 132 is compressed against the wiring pattern 150 to come into contact with the lower end surface of the conductive support metal foil 110. Alternatively to using the insulating composite film 133, the insulating layer may be formed by applying a solution of polyamic acid that is a precursor of a polyimide film. Specifically, the solution is applied to the conductive support metal foil 110 on which the wiring pattern 150 is formed, to a thickness such that the wiring pattern 150 is embedded therein. Subsequently, the precursor is cured to give the insulating layer.

By compressing the insulating composite film 133 as described above, at least the lower end portion of the wiring pattern 150 is embedded in the insulating layer. Preferably, the thermosetting adhesive layer 132 is in contact with the lower end surface of the conductive support metal foil 110. Thereafter, the conductive support metal foil 110 is removed by etching. The conductive support metal foil 110 is generally a copper foil and can be removed by contact with a copper etching solution containing cupric chloride, hydrochloric acid and hydrogen peroxide. Spraying the copper etching solution is preferable because it can etch the conductive support metal foil 110 more uniformly. The spray etching conditions such as the etching solution temperature may be determined appropriately. Usually, the etching solution temperature is 20 to 60° C. and the spray etching time is 10 to 600 seconds.

When the etching solution is sprayed to the conductive support metal foil 110, the conductive support metal foil 110 is dissolved and removed. Consequently, the cured adhesive layer 132 is exposed in areas without the wiring pattern. The conductive support metal foil 110 on the wiring pattern 150 is etched in a similar manner. The wiring pattern 150 has the nodule layer 142 and the optional lumps and covering layer, on which the more noble metal deposit layer 144 is formed. Referring to FIG. 8(h), the nodule layer 142, lumps, covering layer and noble metal deposit layer 144 are deposited in this order in the recess 140 of the conductive support metal foil 110. The wiring main body 128 is deposited on the more noble metal deposit layer 144. Therefore, when the copper etching solution is sprayed to the conductive support metal foil 110, it dissolves the conductive support metal foil 110 first, and then the nodule layer, lumps and covering layer that are formed of copper.

Meanwhile, the more noble metal deposit layer 144 is not dissolved by the copper etching solution and is consequently exposed and protrudes from the insulating layer (cured adhesive layer) 132. The surface of the more noble metal deposit layer 144 shows a considerably rough unevenness which is an inversion of that formed by the nodule layer, lumps and covering layer.

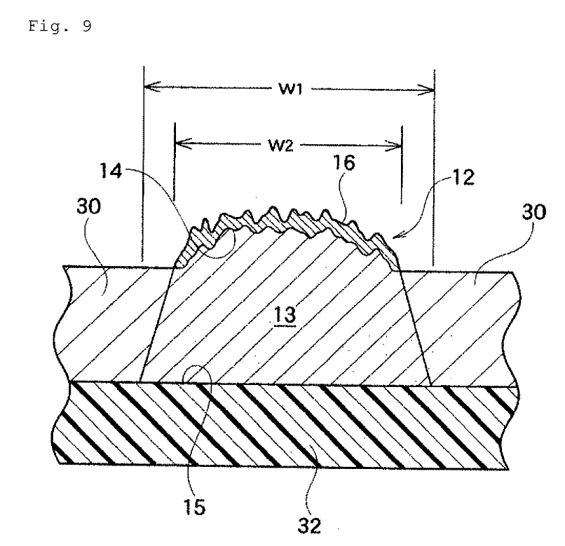

FIG. 9 schematically shows a cross section of the wiring board produced as described above.

As shown, a wiring pattern 12 is formed on an insulating film 32. A lower end portion 15 of a main body 13 of the wiring pattern 12 is in contact with the insulating film 32. The sides of the wiring pattern 12 are covered with a cured adhesive layer 30. An upper end portion 14 of the wiring pattern 12 protrudes from the cured adhesive layer 30. The upper end portion 14 of the wiring pattern 12 has unevenness reflecting the configuration of the nodule layer (and optionally the lumps and covering layer) removed in the previous step. A noble metal deposit layer 16 covers the unevenness.

The uneven upper end portion of the wiring pattern works advantageously in establishing an electrical connection. Specifically, when the wiring board having an electronic component for driving LCD is electrically connected with a terminal of an LCD substrate, an electrical connection can be established with an adhesive alone without the need of an anisotropic conductive adhesive containing conductive particles. Moreover, the electrical connection has higher reliability than that obtained with conductive particles.

The uneven upper end portion of the wiring is usually based on gold and does not have high strength. When a transparent substrate such as ITO is mounted on the wiring pattern with an adhesive free from a conductive metal therebetween, the unevenness reflecting the configuration of the nodule layer (hereinafter, referred to as the nodule replica) is compressed and deformed, and is electrically connected with the ITO substrate, providing an electrical connection between the wiring pattern and the ITO substrate. Specifically, compressing the nodule replica against the ITO substrate deforms the nodule replica to create contacts therebetween through a relatively large area. The nodule replica compressed establishes a good electrical connection between the wiring board of the invention and the ITO substrate, without conductive particles as used in ACF.

The wiring pattern in the wiring board of the present invention has a trapezoidal cross section with the wider bottom portion embedded in the insulating layer. This structure permits the wiring pattern to show high adhesion to the insulating layer even when the pitch is extremely small such as not more than 20 μm. Consequently, the present invention prevents defective wirings separated from the insulating layer. Furthermore, the processes of the invention form the wiring by other than etching a copper foil and therefore the wiring produced has a uniform width. Consequently, the wiring resistance is not varied within the wiring due to uneven width.

Furthermore, the electrically noble wiring surface such as gold provides high temporal stability of the wiring pattern.

Because the wiring is embedded in the insulating layer, no extra metal is present between the wires. Moreover, the surface of the wiring pattern exposed from the insulating layer is formed of an electrically noble metal such as gold. Consequently, short circuits by migration between neighboring wires are prevented.

The wiring pattern in the wiring board of the invention has a uniform line width without variation even at small pitches. The insulating layer in which the wiring is embedded prevents insulation failure due to migration, and the embedded wires are electrically insulated from each other with very high stability.

The above description describes processes for manufacturing a wiring according to the present invention, but the processes are not limited thereto. The processes of the present invention may be applied even to manufacturing of wiring boards having device holes. In such manufacturing, an insulating film having a device hole may be subjected to a backing treatment to coat the device hole, then a wiring pattern may be formed as described above, and the backing material in the device hole may be removed.

### EXAMPLES

The wiring boards according to the present invention will be described below by Examples without limiting the scope of the invention.

### Example 1

A support electrodeposited copper foil 48 mm in width and 35 μm in thickness (VLP copper foil manufactured by MITSUI MINING & SMELTING CO., LTD.) was roll coated with a positive typed photoresist (FR200-8CP manufactured by Rohm and Hass Company) to a thickness of 6 μm. The photoresist was dried and cured at 100° C. for 1 minute, and was exposed with an exposure apparatus to draw a pattern at 20 μm pitches.

The exposure apparatus was EP-70SAC-02 (manufactured by USHIO INC., light intensity: 64 mW/cm²) capable of emitting energy beams with dominant wavelengths of 365 nm, 405 nm and 436 nm. The energy density was 630 mJ/cm². The resist was developed by being soaked in a 1.5% KOH solution for 65 seconds. The bottom opening and the top opening were 6.9 μm and 12.2 μm in width respectively.

Electroplating was performed for 1 minute using a gold plating solution (TEMPEREX 8400 manufactured by EEJA) at 65° C. and Dk of 0.2 A/dm², resulting in a 0.1 μm thick gold deposit layer in the bottom opening of the pattern.

Subsequently, copper was deposited in the opening of the pattern using a copper plating solution at 25° C. and Dk of 2 A/dm² for 18 minutes with stirring. The copper plating solution used herein contained a copper sulfate plating additive (COPPER GLEAM ST-901 manufactured by Rohm and Hass Company). Consequently, a copper deposit layer was formed in a thickness of 8 μm in the opening of the cured resin pattern. The copper pattern had pitches of 20 μm.

After the copper pattern was formed, the photoresist was removed by treatment with a 10% aqueous NaOH solution at room temperature for 15 seconds. Consequently, a predetermined protrudent copper circuit having an inverted trapezoidal cross section was formed on the copper foil.

Separately, a polyimide tape with an adhesive layer (Elephane FC manufactured by TOMOEGAWA Co., Ltd.) was prepared. This polyimide tape included a 48 mm wide polyimide film (UPILEX manufactured by UBE INDUSTRIES, LTD., thickness: 50 μm) and a polyamideimide resin adhesive (X adhesive manufactured by TOMOEGAWA Co., Ltd.) applied in a thickness of 12 μm on one surface of the polyimide film.

The polyimide tape and the copper foil were laminated in a manner such that the adhesive layer and the copper deposit circuit faced each other.

They were hot pressed at 180° C. and 2.5 kg/mm² for 6 hours. By the hot pressing, the adhesive was cured while the copper deposit circuit was embedded therein. Consequently, a laminate was produced which included the polyimide film, the cured adhesive layer in which the copper deposit circuit was embedded, and the copper foil.

Subsequently, an etching solution containing cupric chloride, hydrochloric acid and hydrogen peroxide was sprayed to the copper foil of the laminate at a solution temperature of 40° C. for 1 minute. The copper foil of the laminate was thereby etched, and the cured adhesive layer was exposed.

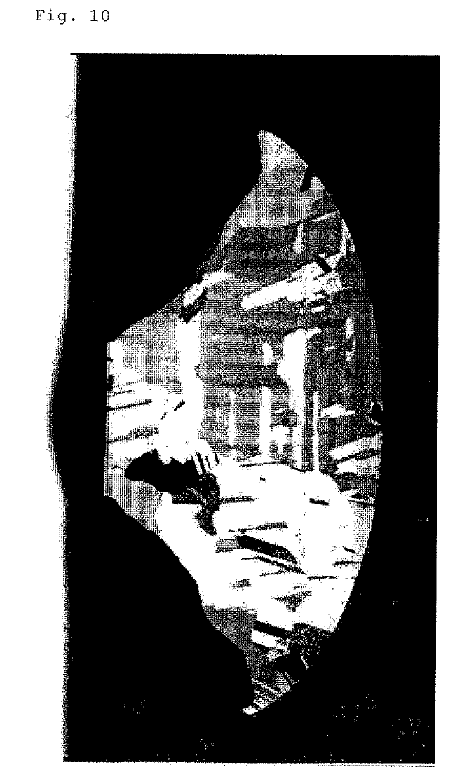

By etching the copper foil, the gold deposit layer representing an upper end portion of the wiring pattern was also exposed on the same surface as the cured adhesive layer on the polyimide film. The wiring pattern had a substantially trapezoidal cross section as shown in FIG. 10. The embedded wiring pattern had a pitch of 20 μm, a thickness of 7.4 μm, a bottom width of 15.7 μm, and a top width of 4.4 μm. The wider bottom and the narrower top formed a trapezoidal cross section. In FIG. 10, the wiring pattern is covered with a deposit layer (carbon) for observation.

The wiring board manufactured as described above was subjected to a peel strength test using cellophane tape. Stripping the cellophane tape from the wiring board did not peel the wiring pattern.

### Example 2

A support electrodeposited copper foil 70 mm in width and 35 μm in thickness (VLP copper foil manufactured by MITSUI MINING & SMELTING CO., LTD.) was roll coated with a positive typed photoresist (FR200-8CP manufactured by Rohm and Hass Company) to a thickness of 6.8 μm. The photoresist was dried and cured at 100° C. for 1 minute, and was exposed with an exposure apparatus to draw a pattern at 20 μm pitches.

The exposure apparatus was EP-70SAC-02 (manufactured by USHIO INC., light intensity: 64 mW/cm²) capable of emitting energy beams with dominant wavelengths of 365 nm, 405 nm and 436 nm. The energy density was 630 mJ/cm². The resist was developed by being soaked in a 1.5% KOH solution for 65 seconds. The bottom opening and the top opening were 6.2 μm and 11.5 μm in width respectively.

Electroplating was performed for 1 minute using a gold plating solution (TEMPEREX 8400 manufactured by EEJA) at 65° C. and Dk of 0.2 A/dm², resulting in a 0.1 μm thick gold deposit layer in the bottom opening of the pattern.

Subsequently, copper was deposited in the opening of the pattern using a copper plating solution at 25° C. and Dk of 4 A/dm² for 9 minutes with stirring. The copper plating solution used herein contained a copper sulfate plating additive (COPPER GLEAM ST-901 manufactured by Rohm and Hass Company). Consequently, a copper deposit layer was formed in a thickness of 8 μm in the opening of the cured resin pattern. The copper pattern had pitches of 20 μm.

After the copper pattern was formed, the photoresist was removed by treatment with a 10% aqueous NaOH solution at room temperature for 15 seconds. Consequently, a predetermined protrudent copper circuit having an inverted trapezoidal cross section was formed on the copper foil.

Separately, pyromellitic acid and diamine were reacted at a low temperature to give an N-methylpyrrolidone solution of polyamic acid.

The N-methylpyrrolidone solution of polyamic acid was applied twice to the copper foil using a lip coater at a solution temperature of 60° C. to cover the inverted trapezoidal copper circuit. The coating resin thickness was 40 μm, The coating was heated at 370° C. for 3 hours to dehydrate and ring-close the polyamic acid. By-product water was removed.

The laminate produced as described above was cut to a width of 48 mm.

Subsequently, an etching solution containing cupric chloride, hydrochloric acid and hydrogen peroxide was sprayed to the copper foil of the laminate at a solution temperature of 40° C. for 1 minute. The copper foil of the laminate was thereby etched.

Etching the copper foil exposed the polyimide resulting from the ring-closing reaction of polyamic acid. The gold deposit layer representing an upper end portion of the wiring pattern was also exposed on the same surface as the polyimide.

The wiring pattern had a thickness of 8 μm, a bottom width of 12 μm, and a top width of 6 μm.

The wiring board manufactured as described above was subjected to a peel strength test using cellophane tape. Stripping the cellophane tape from the wiring board did not peel the wiring pattern.

### Example 3

An electrodeposited copper foil 3 μm in thickness (MicroThin copper foil manufactured by MITSUI MINING & SMELTING CO., LTD.) was laminated to an adhesive-coated PET film 48 mm in width and 50 μm in thickness. To the resultant two-layer laminate film, an etching solution having a temperature of 40° C. was sprayed for 20 seconds from nozzles located 15 cm above the laminate film. Consequently, the copper foil was etched to a thickness of 1 μm. The etching solution used herein had a hydrochloric acid concentration of 85.4 to 87.6 g/l, a Cu ion concentration of 115 to 135 g/l, and a specific gravity of 1.250 to 1.253. The etching solution was sprayed from two nozzles at a pressure of 2 kg/cm² and a flow rate of 1.83 l/min per nozzle.

The half-etched copper foil was roll coated with a positive typed photoresist (FR200-8CP manufactured by Rohm and Hass Company) to a thickness of 6.5 μm. The photoresist was dried and cured at 100° C. for 1 minute, and was exposed with an exposure apparatus to draw a pattern at 20 μm pitches.

The exposure apparatus was EP-70SAC-02 (manufactured by USHIO INC. , light intensity: 64 mW/cm²) capable of emitting energy beams with dominant wavelengths of 365 nm, 405 nm and 436 nm. The energy density was 630 mJ/cm². The resist was developed by being soaked in a 1.5% NOH solution for 65 seconds. The bottom opening and the top opening were 6.4 μm and 11.8 μm in width respectively.

Electroplating was performed for 1 minute using a gold plating solution (TEMPEREX 8400 manufactured by EEJA) at 65° C. and Dk of 0.2 A/dm², resulting in a 0.1 μm thick gold deposit layer in the bottom opening of the pattern.

Subsequently, copper was deposited in the opening of the pattern using a copper plating solution at 25° C. and Dk of 3 A/dm² for 6 minutes with stirring. The copper plating solution used herein contained a copper sulfate plating additive (COPPER GLEAM ST-901 manufactured by Rohm and Hass Company) Consequently, a copper deposit layer was formed in a thickness of 4 μm in the opening of the cured resin pattern. The copper pattern had pitches of 20 μm.

Further, copper was deposited on the copper pattern using a copper plating solution at 25° C. and Dk of 2 A/dm² for 5 seconds with vigorous stirring. Consequently, nodules (copper fine particles) were formed to a height of 4 to 4.5 μm. The copper plating solution used herein had been prepared by adding 200 ppm of α-naphthoquinoline (C₃H₉N) to a solution containing CuSO₄.5H₂O at 32 g/l (Cu=8 g/l) and H₂SO₄ at 100 g/l.

To fix the nodules, copper was deposited thereon using a copper plating solution at 25° C. and Dk of 2 A/dm² for 2 minutes with stirring. Consequently, a covering copper layer was deposited to a thickness of about 1 μm. The copper plating solution used herein contained a copper sulfate plating additive (COPPER GLEAM ST-901 manufactured by Rohm and Hass Company).

Thereafter, the photoresist was removed by treatment with a 10% aqueous NaOH solution at room temperature for 15 seconds. Consequently, a copper circuit having an inverted trapezoidal cross section with the nodules on top of the wiring was formed on the copper foil (laminated to the PET film). The total thickness of the copper circuit was 9.5 μm.

Separately, an adhesive-coated polyimide tape (Elephane SC manufactured by TOMOEGAWA Co. , Ltd.) was prepared. This polyimide tape included a polyimide film 50 μm in thickness and 48 mm in width (UPILEX manufactured by UBE INDUSTRIES, LTD.) and a polyamideimide resin adhesive layer 12 μm in thickness and 42 mm in width (X adhesive manufactured by TOMOEGAWA Co., Ltd.).

The polyimide tape and the copper foil were laminated in a manner such that the adhesive layer faced the nodules on top of the inverted trapezoidal copper circuit. They were preheated at 120° C. and 3 kg/cm² and were continuously laminated with heat rolls at 130° C. and a rate of 3 m/min. Consequently, the polyimide tape and the copper foil were temporarily pressure bonded, with the nodules of the wiring being embedded in the adhesive layer. The 50 μm thick PET film that was the backing material of the MicroThin copper foil was separated by mechanical rolling. The bond strength between the PET film and the MicroThin copper foil was not so high, and the PET film was easily separated from the MicroThin copper foil by rolling the PET film.

After the PET film was removed, the laminate was introduced in a hot air circulation oven and was heated at 70° C. for 4 hours and then at 160° C. for 6 hours to cure the adhesive.

After the laminate was cooled, an etching solution containing cupric chloride, hydrochloric acid and hydrogen peroxide was sprayed to the copper foil of the laminate using the etching device described hereinabove, at a solution temperature of 40° C. for 9 seconds. The MicroThin copper foil of the laminate was thereby etched. Consequently, a wiring board was obtained in which the wires were formed at pitches of 20 μm. The wiring had the nodules embedded in the adhesive layer at the bottom, and the gold deposit layer at top of the wiring.

The thickness of the conductor inclusive of the nodules was 9 to 9.5 μm. Although the sides of the conductor had been slightly etched by the spray etching, the wiring pattern had a bottom width of 12 m and a top width of 5 μm. The wider bottom and the narrower top formed a trapezoidal cross section. Of the trapezoidal wiring pattern, 70% of the slope from the lower end surface was embedded in the adhesive layer.

In the wiring pattern, the nodules embedded in the adhesive layer worked as an anchor to provide high bond strength with respect to the adhesive layer. The wiring board manufactured as described above was subjected to a peel strength test using cellophane tape. Stripping the cellophane tape from the wiring board did not peel the wiring pattern.

### Example 4

An electrodeposited copper foil 48 mm in width and 35 μm in thickness (VLP copper foil manufactured by MITSUI MINING & SMELTING CO., LTD.) was prepared as a support.

A shiny surface of the electrodeposited copper foil was roll coated with a positive typed photoresist (FR200-8CP manufactured by Rohm and Hass Company) to a thickness of 6.8 μm. The photoresist was dried and cured at 100° C. for 1 minute, and was exposed with an exposure apparatus to draw a circuit pattern at pitches of 20 to 100 μm.

The exposure apparatus was EP-70SAC-02 (manufactured by USHIO INC., light intensity: 64 mW/cm²) capable of emitting energy beams with dominant wavelengths of 365 nm, 405 nm and 436 nm. The energy density was 730 mJ/cm². The resist was developed by being soaked in a 1.5% KOH solution for 70 seconds. In the openings at 20 μm pitches, the bottom width and the top width were 8 μm and 13 μm respectively. In the openings at other pitches, the cross section was trapezoidal.

Subsequently, the laminate was introduced to a continuous etching line in which the copper foil was etched to a depth of 6 μm by being sprayed with a 40° C. etching solution for 30 seconds. The etching line included 10 nozzles. The pressure in spraying the etching solution was 2 kg/cm². The nozzles were located 15 cm above the copper foil.

Subsequently, copper was deposited in the recess created in the copper foil, using a copper plating solution at 25° C. and Dk of 50 A/dm² for 6 seconds with vigorous stirring. Consequently, nodules (copper fine particles) were formed to a height of 5 to 5.5 μm. The copper plating solution used herein had been prepared by adding 200 ppm of α-naphthoquinoline (C₃H₉N) to a solution containing CuSO₄.5H₂O at 32 g/l (Cu=8 g/l) and H₂SO₄ at 100 g/l.

To fix the nodules, copper was deposited thereon using a copper plating solution at 25° C. and Dk of 2 A/dm² for 1 minute with stirring. Consequently, a covering copper layer was deposited to a thickness of about 0.5 μm. The copper plating solution used herein contained a copper sulfate plating additive (COPPER GLEAM ST-901 manufactured by Rohm and Hass Company)

Electroplating was performed for 2 minutes using a gold plating solution (TEMPEREX 8400 manufactured by EEJA) at 65° C. and Dk of 0.2 A/dm², resulting in a 0.2 μm thick gold deposit layer.

Subsequently, copper was deposited in the opening of the pattern using a copper plating solution at 25° C. and Dk of 3 A/dm² for 12 minutes with stirring. The copper plating solution used herein contained a copper sulfate plating additive (COPPER GLEAM ST-901 manufactured by Rohm and Hass Company). Consequently, a copper circuit was formed in a thickness of 8 μm in the opening of the pattern. The copper circuit had pitches of 20 to 100 μm corresponding to the pattern.

Thereafter, the photoresist was removed by treatment with a 10% aqueous NaOH solution at room temperature for 15 seconds. Consequently, a copper circuit was formed in a thickness of 7 μm on the support copper foil.

Separately, an adhesive-coated polyimide tape (Elephane FC manufactured by TOMOEGAWA Co., Ltd.) was prepared. This polyimide tape included a polyimide film 50 μm in thickness and 48 mm in width (UPILEX manufactured by UBE INDUSTRIES, LTD.) and a polyamideimide resin adhesive layer 7 μm in thickness and 42 mm in width (X adhesive manufactured by TOMOEGAWA Co., Ltd.).

The polyimide tape and the copper foil were laminated in a manner such that the adhesive layer faced the copper circuit. They were preheated at 120° C. and were continuously laminated with heat rolls at 130° C., 6 kg/cm² and a rate of 3 m/min. Consequently, the polyimide tape and the copper foil were temporarily pressure bonded, with a lower end portion of the copper circuit being embedded in the adhesive layer. Consequently, a laminate was produced which included the polyimide film, the adhesive layer in which the lower end portion of the copper circuit was embedded, and the support copper foil.

The laminate was wound on a reel together with a polyimide spacer film. The wound laminate was introduced in a hot air circulation oven and was heated at 70° C. for 4 hours and then at 160° C. for 6 hours to cure the adhesive.

The laminate was unwound and was sprayed with an etching solution containing cupric chloride, hydrochloric acid and hydrogen peroxide at a solution temperature of 40° C. for 1.5 minutes. The support copper foil was thereby etched. The etching also removed the nodules formed in the recesses of the support copper foil, and consequently exposed the underlying gold deposit layer on the surface of the copper circuit. The gold deposit layer had been formed along the nodules and therefore reproduced an inversed configuration of the nodules.

In the copper circuit, the gold deposit layer was exposed and protruded from the cured adhesive layer. A portion of the copper circuit below the gold deposit layer was embedded in the cured adhesive layer.

The wiring board manufactured as described above was subjected to a peel strength test using cellophane tape. Stripping the cellophane tape from the wiring board did not peel the wiring pattern formed at pitches of 20 to 100 μm.

### INDUSTRIAL APPLICABILITY

In the wiring boards according to the invention, the wiring pattern has a trapezoidal cross section in which the shorter side is exposed from the insulating layer and the longer side is embedded in the insulating layer. This structure prevents the wiring from being separated from the insulating layer even when the wiring pattern has a small line width. The wires are discrete from each other without any metals that can cause migration therebetween. Therefore, the wiring boards have very high insulation between wires and long-term high insulation reliability.

The upper end portion exposed from the insulating layer is gold or the metals having lower ionization energy than the wiring metals, and therefore the wiring is very stable for a long period of time without property changes.

According to an embodiment of the present invention, the surface of the wiring is a finely uneven gold deposit layer. Such uneven deposit layer can establish an electrical connection with a terminal through an adhesive alone. That is, an anisotropic conductive adhesive containing conductive metal particles is not always required. Moreover the electrical connection is much more stable than that obtained with the conventional anisotropic conductive adhesives.

1. A wiring board comprising an insulating substrate and a wiring pattern, the wiring pattern including a main body and an upper end portion and being embedded in the insulating substrate while exposing at least the upper end portion on a surface of the insulating substrate, the upper end portion having a cross-sectional width smaller than that of a lower end portion of the wiring pattern embedded in the insulating substrate, the upper end portion comprising a metal which is more noble than a metal of the main body of the wiring pattern.

2. The wiring board according to claim 1, wherein the main body of the wiring pattern is embedded in the insulating substrate and an upper end surface of the upper end portion of the wiring pattern is exposed on the surface of the insulating substrate.

3. The wiring board according to claim 1, wherein the wiring board further comprises a nodule deposit layer on a lower end surface of the lower end portion of the wiring pattern, and at least the nodule deposit layer is embedded in the insulating substrate.

4. The wiring board according to claim 1, wherein the wiring pattern is embedded in the insulating substrate to a depth of at least 20% of the length of a slope of the wiring pattern from the lower end surface.

5. The wiring board according to claim 1, wherein the insulating substrate comprises at least one insulating resin selected from the group consisting of polyimides, epoxy resins, polyamic acids and polyamideimides.

6. The wiring board according to claim 1, wherein the more noble metal forming the upper end portion of the wiring pattern exposed on the insulating substrate includes at least one metal selected from the group consisting of gold, silver and platinum.

7. The wiring board according to claim 1, wherein the metal forming the main body of the wiring pattern is copper or a copper alloy.

8. The wiring board according to claim 1, wherein the upper end portion of the wiring pattern has a cross-sectional width in the range of 40 to 99% of that of the lower end portion.

9. The wiring board according to claim 1, wherein the upper end portion comprising the more noble metal has a thickness of 0.01 to 3 μm.

10. A process for manufacturing a wiring board, comprising the steps of:
forming a photosensitive resin layer on a surface of a conductive support metal foil;
exposing the photosensitive resin layer and developing a latent image to form a groove for forming a wiring pattern, the groove having a bottom opening facing the conductive support metal foil, the bottom opening having a width smaller than that of a surface opening;
depositing a conductive metal on the conductive support metal foil exposed from the bottom opening of the groove, the conductive metal being more noble than a metal of the conductive support metal foil;
depositing a conductive metal on the noble conductive metal, the conductive metal being less noble than the noble conductive metal and filling the groove to form a wiring pattern;
removing the resin layer;
forming an insulating layer on the conductive support metal foil exposed by the removal of the resin layer, for embedding the wiring pattern in the insulating layer; and
removing the conductive support metal foil by etching to expose the insulating layer and the more noble metal forming an upper end portion of the wiring pattern.

11. The process according to claim 10, wherein the step for embedding the wiring pattern in an insulating layer is performed by applying a resin precursor capable of forming a resin of the insulating layer to a surface of the conductive support metal foil exposed by the removal of the resin layer, and curing the resin precursor.

12. The process according to claim 10, wherein the step for embedding the wiring pattern in an insulating layer is performed by applying an insulating composite film to a surface of the conductive support metal foil exposed by the removal of the resin layer, the insulating composite film having an insulating resin film and a thermosetting adhesive layer, and heating the insulating composite film to cure the thermosetting adhesive layer while the wiring pattern is embedded in the thermosetting adhesive layer.

13. A process for manufacturing a wiring board, comprising the steps of:
forming a photosensitive resin layer on a surface of a conductive support metal foil;
exposing the photosensitive resin layer and developing a latent image to form a groove for forming a wiring pattern, the groove having a bottom opening facing the conductive support metal foil, the bottom opening having a width smaller than that of a surface opening;
depositing a conductive metal on the conductive support metal foil exposed from the bottom opening of the groove, the conductive metal being more noble than a metal of the conductive support metal foil;
depositing a conductive metal on the noble conductive metal, the conductive metal being less noble than the noble conductive metal and filling the groove to form a wiring pattern, and forming a nodule layer on a bottom of the wiring pattern;
removing the resin layer;
embedding the wiring pattern and the nodule layer in an insulating layer; and
removing the conductive support metal foil by etching to expose the insulating layer and the more noble metal forming an upper end portion of the wiring pattern.

14. The process according to claim 13, wherein the step for embedding the wiring pattern in an insulating layer is performed by applying a resin precursor capable of forming a resin of the insulating layer to a surface of the conductive support metal foil exposed by the removal of the resin layer, and curing the resin precursor.

15. The process according to claim 13, wherein the step for embedding the wiring pattern in an insulating layer is performed by applying an insulating composite film to a surface of the conductive support metal foil exposed by the removal of the resin layer, the insulating composite film having an insulating resin film and a thermosetting adhesive layer, and heating the insulating composite film to cure the thermosetting adhesive layer while the wiring pattern is embedded in the thermosetting adhesive layer.

16. A process for manufacturing a wiring board, comprising the steps of:
half etching a conductive metal foil laminated on a flexible support resin film, the conductive metal foil and the flexible support resin film forming a composite support film in combination, the half etching resulting in a composite support having an extremely thin conductive metal layer;
applying a photosensitive resin on the extremely thin conductive metal layer of the composite support to form a photosensitive resin layer, and exposing the photosensitive resin layer and developing a latent image to form a groove for forming a wiring pattern, the groove having a bottom opening facing the extremely thin conductive metal layer, the bottom opening having a width smaller than that of a surface opening;
depositing a conductive metal on the extremely thin conductive metal layer exposed from the bottom opening of the groove, the conductive metal being more noble than a metal of the extremely thin conductive metal layer;
depositing a conductive metal on the noble conductive metal, the conductive metal being less noble than the noble conductive metal and filling the groove to form a wiring pattern, and forming a nodule layer on a bottom of the wiring pattern;
removing the resin layer;
embedding the wiring pattern and the nodule layer in an insulating layer; and
removing the conductive support metal foil by etching to expose the insulating layer and the more noble metal forming an upper end portion of the wiring pattern.

17. The process according to claim 16, wherein the step for embedding the wiring pattern in an insulating layer is performed by applying a resin precursor capable of forming a resin of the insulating layer to a surface of the conductive support metal foil exposed by the removal of the resin layer, and curing the resin precursor.

18. The process according to claim 16, wherein the step for embedding the wiring pattern in an insulating layer is performed by applying an insulating composite film to a surface of the conductive support metal foil exposed by the removal of the resin layer, the insulating composite film having an insulating resin film and a thermosetting adhesive layer, and heating the insulating composite film to cure the thermosetting adhesive layer while the wiring pattern is embedded in the thermosetting adhesive layer.

19. A process for manufacturing a wiring board, comprising the steps of:
forming a photosensitive resin layer on a surface of a conductive support metal foil;
exposing the photosensitive resin layer and developing a latent image to form a groove in which the conductive support metal foil is exposed from the resin layer, the groove having a bottom opening facing the conductive support metal foil, the bottom opening having a width smaller than that of a surface opening;
half etching the conductive support metal foil with use of the resin layer as a masking material to form a recess in the conductive support metal foil;
forming a nodule layer on a surface of the recess of the conductive support metal foil, and depositing a metal layer in the recess in which the nodule layer has been formed, the metal layer comprising a metal that is more noble than a metal of the nodule layer;
depositing a metal in a recess which is defined by the resin layer and the half etched conductive support metal foil and includes the nodule layer and the more noble metal layer, the metal being less noble than the metal of the more noble metal layer, the metal filling the convex to form a wiring pattern;
removing the resin layer;
embedding the wiring pattern in an insulating layer; and
removing the conductive support metal foil and the nodule layer by etching to expose the insulating layer and the more noble metal forming an upper end portion of the wiring pattern.

20. The process according to claim 19, wherein the conductive support metal foil has a support resin film on a surface opposite to the surface with the photosensitive resin layer.

21. The process according to claim 19, wherein the step for embedding the wiring pattern in an insulating layer is performed by applying a resin precursor capable of forming a resin of the insulating layer to a surface of the conductive support metal foil exposed by the removal of the resin layer, and curing the resin precursor.

22. The process according to claim 19, wherein the step for embedding the wiring pattern in an insulating layer is performed by applying an insulating composite film to a surface of the conductive support metal foil exposed by the removal of the resin layer, the insulating composite film having an insulating resin film and a thermosetting adhesive layer, and heating the insulating composite film to cure the thermosetting adhesive layer while the wiring pattern is embedded in the thermosetting adhesive layer.

23. The process according to claim 19, further comprising a step of forming a nodule on a bottom of the wiring pattern to be embedded in the insulating layer.
